(19) United States
(12) Patent Application Publication
(10) Pub. No.: US 2015/0263267 A1
(43) Pub. Date: Sep. 17, 2015

(54) MAGNETIC MEMORY AND METHOD FOR MANUFACTURING THE SAME

(71) Applicant: Hiroyuki KANAYA, Seoul (KR)

(72) Inventor: Hiroyuki KANAYA, Seoul (KR)

(21) Appl. No.: 14/481,541

(22) Filed: Sep. 9, 2014

Related U.S. Application Data
(60) Provisional application No. 61/952,801, filed on Mar. 13, 2014.

(51) Int. Cl. H01L 43/08; H01L 43/12; H01L 43/02

(52) U.S. Cl. CPC H01L 43/08; H01L 43/02; H01L 43/12

(57) ABSTRACT

One embodiment discloses a magnetic memory. The magnetic memory includes a substrate, an electrode provided on the substrate, a member provided on the electrode and having an amorphous structure, and a magnetoresistive element provided on the member. The magnetoresistive element is located within a closed curve defining a contour of an upper surface of the member.

### CROSS-REFERENCE TO RELATED APPLICATIONS

This application claims the benefit of U.S. Provisional Application No. 61/952,801, filed Mar. 13, 2014, the entire contents of which are incorporated herein by reference.

### FIELD

Embodiments described herein relate generally to a magnetic memory and a method for manufacturing the same.

### BACKGROUND

In recent years, a semiconductor memory using a resistance change element as a storage element, such as a PRAM (phase-change random access memory) or an MRAM (magnetoresistive random access memory) has been attracting attention and been developed. The MRAM is a device which performs a memory operation by storing binary 1 or 0 in a memory cell by using magnetoresistance, and features nonvolatility, high-speed operation, high integration, and high reliability.

One of the magnetoresistive elements is a magnetic tunnel junction (MTJ) element including a laminated structure of three layers, namely, a storage layer having a variable magnetization direction, an insulating film as a tunnel barrier, and a reference layer maintaining a predetermined magnetization direction.

The resistance of the MTJ element varies with the magnetization directions of the storage layer and the reference layer, has a minimum value when the magnetization directions are parallel and has a maximum value when the magnetization directions are antiparallel, and stores information by associating the parallel state and the antiparallel state with binary 0 and 1.

There are schemes for writing information on the MTJ element: one is a magnetic field writing scheme in which only the magnetization direction of the storage layer is reversed by a current magnetic field generated when a current flows through a write line, and another is a writing scheme (of spin-injection) using spin angular momentum transfer in which the magnetization direction of the storage layer is reversed by passing a spin-polarized current through the MTJ element itself.

In the former scheme, when the element size is reduced, the coercivity of the magnetic body constituting the storage layer increases, and thus the write current tends to increase. Consequently, it is difficult to achieve both miniaturization and low current.

In the latter scheme (spin-injection writing scheme), on the other hand, the smaller the magnetic layer constituting the storage layer is in volume, fewer spin-polarized electrons will need to be injected. Therefore, it is expected that miniaturization and low current can both be easily achieved.

### BRIEF DESCRIPTION OF THE DRAWINGS

FIGS. 1A and 1B are sectional views for explaining a method for manufacturing a magnetic memory according to a first embodiment;

FIG. 2 is a sectional view for explaining the method for manufacturing the magnetic memory following FIG. 1A;

FIG. 3 is a sectional view for explaining the method for manufacturing the magnetic memory following FIG. 2;

FIG. 4 is a sectional view for explaining the method for manufacturing the magnetic memory following FIG. 3;

FIG. 5 is a sectional view for explaining the method for manufacturing the magnetic memory following FIG. 4;

FIG. 6 is a sectional view for explaining the method for manufacturing the magnetic memory following FIG. 5;

FIG. 7 is a sectional view for explaining the method for manufacturing the magnetic memory following FIG. 6;

FIG. 8 is a sectional view for explaining the method for manufacturing the magnetic memory following FIG. 7;

FIG. 9 is a sectional view for explaining the method for manufacturing the magnetic memory following FIG. 8;

FIG. 10 is a sectional view for explaining a method for manufacturing a magnetic memory according to a second embodiment;

FIG. 11 is a sectional view for explaining the method for manufacturing the magnetic memory following FIG. 10;

FIG. 12 is a sectional view for explaining the method for manufacturing the magnetic memory following FIG. 11;

FIG. 13 is a sectional view for explaining the method for manufacturing the magnetic memory following FIG. 12;

FIG. 14 is a sectional view for explaining the method for manufacturing the magnetic memory following FIG. 13;

FIG. 15 is a sectional view for explaining the method for manufacturing the magnetic memory following FIG. 14;

FIG. 16 is a sectional view for explaining the method for manufacturing the magnetic memory following FIG. 15;

FIG. 17 is a sectional view for explaining the method for manufacturing the magnetic memory following FIG. 16;

FIG. 18 is a sectional view for explaining the method for manufacturing the magnetic memory following FIG. 17; and

FIG. 19 is a sectional view for explaining the method for manufacturing the magnetic memory following FIG. 18.

### DETAILED DESCRIPTION

One embodiment discloses a magnetic memory. In general, the magnetic memory includes a substrate, an electrode provided on the substrate, a member provided on the electrode and having an amorphous structure, and a magnetoresistive element provided on the member. The magnetoresistive element is located within a closed curve defining a contour of a top surface of the member.

Another embodiment discloses another magnetic memory. In general, the magnetic memory includes a substrate, an electrode provided on the substrate, a first conductive layer provided on the electrode, an insulating layer provided on the first conductive layer and having an amorphous structure, and a second conductive layer provided on the insulating layer. The magnetic memory further includes a third conductive layer provided on the side surfaces of the first conductive layer, the insulating layer and the second conductive layer and connected to the electrode, and a magnetoresistive element provided on the second conductive layer.

Still another embodiment discloses a method for manufacturing a magnetic memory. In general, the method includes forming an electrode on a substrate, forming an insulating film in a region including the electrode, forming a through hole communicating with the electrode in the insulating film filling the through hole with a conductive layer and a amorphous member, the conductive layer covering a side surface and a bottom surface of the through hole, and the member filling the through hole via the conductive layer. The method further includes forming a magnetoresistive element on the member, the magnetoresistive element being located within a closed curve defining a contour of an upper surface of the member.

The magnetic memory according to one embodiment will now be described according to its manufacturing method with reference to the accompanying drawings. In the drawings, portions identical to each other are denoted by the same reference numbers. Further, the same description may be repeated as necessary.

### First Embodiment

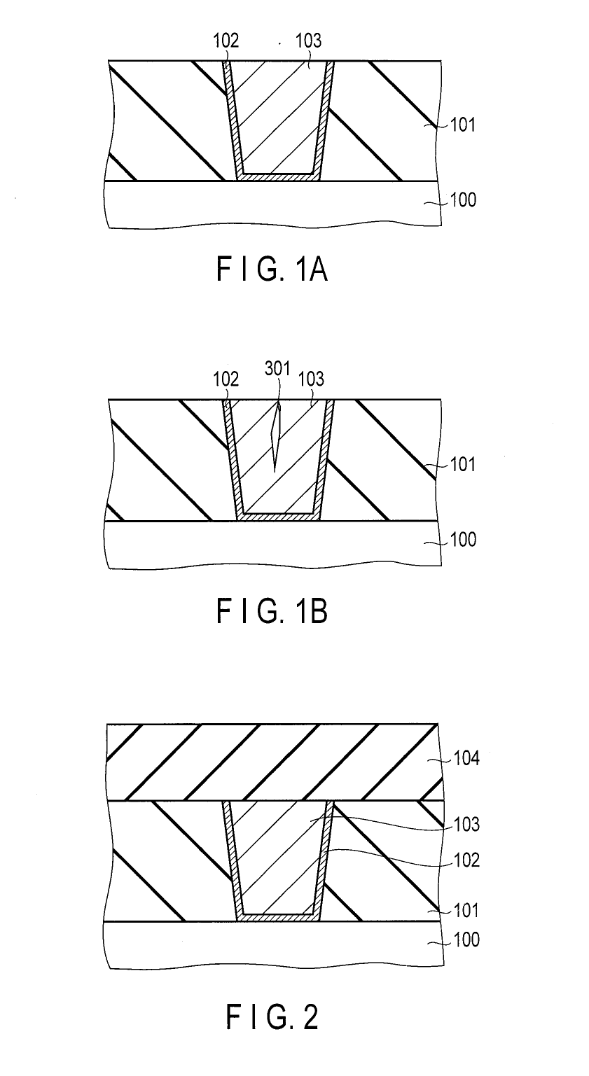

FIGS. 1 to 9 are sectional views for explaining a method for manufacturing a magnetic memory according to the present embodiment. In the present embodiment, the case where the magnetic memory is an MRAM (magnetic random access memory) will be described.

[FIG. 1A, FIG. 1B]

An interlayer dielectric film 101 is formed on a substrate 100 including a silicon substrate (not shown), and a lower electrode (plug) 103 is formed in the interlayer dielectric film 101 via a barrier metal film 102 by the well-known damascene process. The lower electrode 103 may have no seam as shown in FIG. 1A, or may have a seam as shown in FIG. 1B. In the drawings subsequent to FIGS. 1A and 1B, although there are also both cases with the seam and without the seam, drawings for the case with the seam are omitted for the sake of brevity.

The interlayer dielectric film 101 is a silicon dioxide film (SiO2), for example. The barrier metal film 102 includes, for example, a laminated film of a Ti film and a TiN film. A material of the lower electrode 103 includes tungsten (W) or titanium nitride (TiN), for example. Depending on the material of the lower electrode 103, the barrier metal film 102 may not be needed.

A selection transistor (not shown) is formed on a surface of the silicon substrate. The select transistor is an element for selecting an MTJ element. The select transistor is a surrounding gate transistor (SGT), for example. A gate insulating film and a gate electrode of the SGT are embedded in the surface of the silicon substrate. In the select transistor, one source/train region is connected to the lower electrode 103 and the other source/drain region is connected to the plug (not shown).

[FIG. 2]

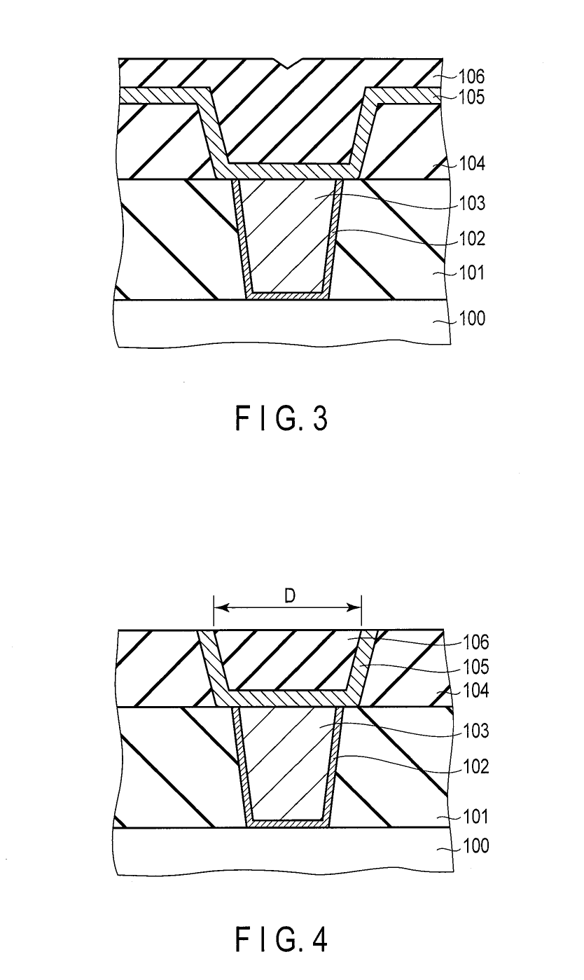

An interlayer dielectric film 104 is deposited on the interlayer dielectric film 101, the barrier metal film 102 and the lower electrode 103 by CVD (chemical vapor deposition) process, and then a surface of the interlayer dielectric film 104 is planarized by CMP (chemical mechanical polishing) process. The interlayer dielectric film 104 is a silicon dioxide film, for example.

[FIG. 3]

A through hole (connecting hole) communicating with the barrier metal film 102 and the lower electrode 103 is formed in the interlayer dielectric film 104, a conductive film 105 covering an inner surface (bottom surface and side surface) of the through hole is formed on the entire surface, and then a silicon dioxide film 106 thicker than a depth of the through hole is formed. A material of the conductive film 105 is TiN or WN, for example. The silicon dioxide film 106 is formed with a thickness of 100 Å or more, for example, by CVD process. By making the thickness 100 Å or more, it is possible to form the silicon dioxide 106 which has an amorphous structure at least in its upper surface portion.

In the present embodiment, a plane pattern of the through hole is circular. Since the silicon dioxide film 106 is amorphous, a seam will not likely to be created in the silicon dioxide film 106 even if a seam is created in the conductive film 105 under the silicon oxide film 106. One of the causes of creating a seam in the conductive film 105 is a seam created in the lower electrode 103.

[FIG. 4]

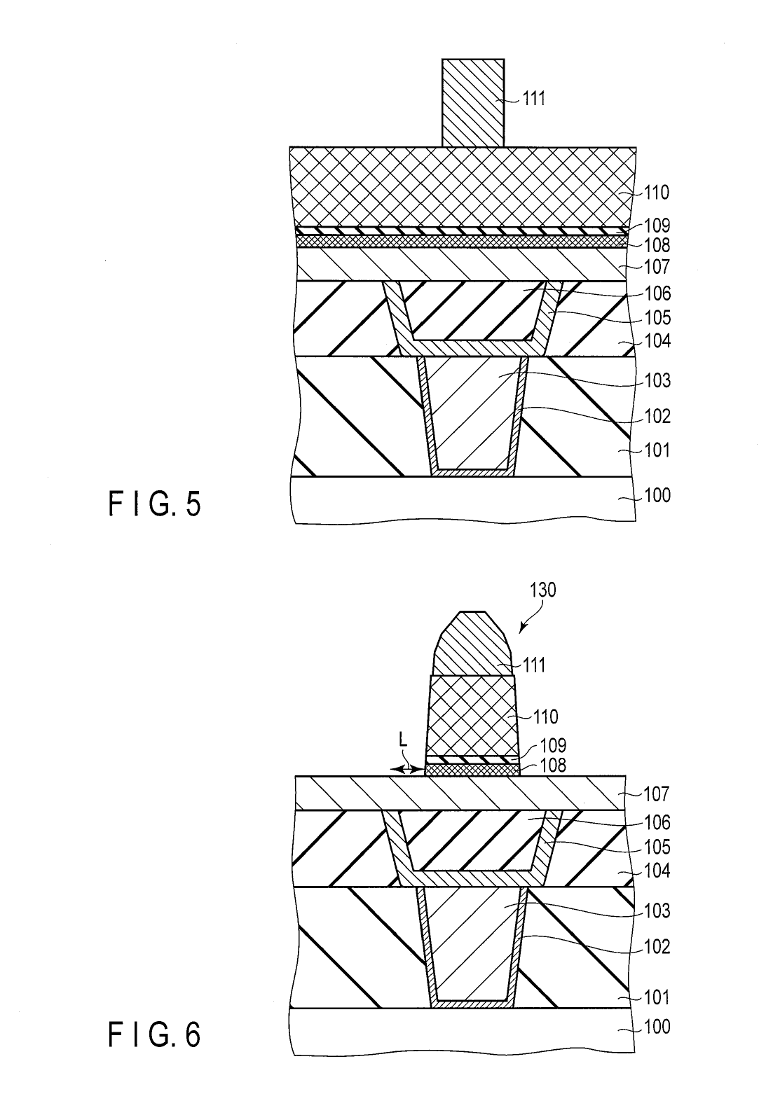

By the CMP process, the portions of the interlayer dielectric film 104, conductive film 105, and silicon dioxide film 106 which are located outside of the through hole are removed, and the surfaces of these films 104 to 106 are planarized. As a result, the inner surface (side surface and bottom surface) of the through hole is covered with the conductive film 105, and the through hole is filled up with the silicon dioxide film 106 via the conductive film 105. Since the plane pattern of the through hole is almost circular (it depends on the device design dimension. For example, diameter D is around less than 60 nm.), an upper surface of the silicon dioxide film 106 is circular. The diameter D of the upper surface of the silicon dioxide film 106 is set larger than the diameter of an MTJ element which is to be formed subsequently.

[FIG. 5]

The layers constituting the MTJ element, which include, for instance, a tantalum layer (first underlying layer) 107, a first magnetic layer 108 as a storage layer, a tunnel barrier layer 109 and a second magnetic layer 110 as a reference layer, are formed consecutively on the surfaces of the planarized interlayer dielectric film 104, conductive film 105, and silicon oxide film 106. The tantalum layer 107, the magnetic layers 108, 110 are formed by, for example, sputter process.

Since the silicon dioxide film 106 has a flat surface and no seam is created therein, the tantalum layer 107, first magnetic layers 108, tunnel barrier layer 109, and second magnetic layer 110 are formed evenly on the silicon oxide film 106.

Other than the first magnetic layer 108, the tunnel barrier layer 109 and the second magnetic layer 110, a shift cancelling layer (not shown), for example, may also be one of the layers constituting the MTJ element. The shift cancelling layer may be formed on the second magnetic layer 110. The first and second magnetic layers 120 and 122 may be a reference layer and a storage layer, respectively.

Subsequently, a conductive hard mask 111 is formed on the second magnetic layer 110. A material of the hard mask 111 is TiN, Ti, Ta or W, for example. If the shift cancelling layer has been formed on the second magnetic layer 110, the hard mask 11 is formed on the shift cancelling layer.

[FIG. 6]

Using the hard mask 111 as a mask, the second magnetic layer 110, tunnel barrier layer 109 and first magnetic layer 108 are etched consecutively, thereby forming an MTJ element 130. In this case and some cases, some part of the tantalum layer 107 is also etched. The etching amount of some part of the tantalum layer 107 is very small (for example, less than 1 nm), so that none of the tantalum layer 107 seems to be etched in FIG. 6. When the tantalum layer 107 is etched, the tantalum layer 107 comprises a sidewall which is formed by the etching.

In the above etching, for example, RIE (reactive ion etching), IBE (ion beam etching), or a combination of RIE and IBE may be used.

In the present embodiment, a plane pattern of the MTJ element 130 is almost circular. However, the plane pattern may be rectangular. In the present embodiment, basically, the laminated body of layers 108, 109, 110 and 111 constituting the MTJ element 130 has a taper shape with a width decreasing toward the top, and thus the diameter of the first magnetic layer 108 is the largest among layers 108, 109, 110 and 111 constituting the MTJ element 130. The shape of the laminated body of layers 108, 109, 110 and 111 is not limited to the taper shape, the shape depends on condition of the etching which employs at least one of the IBE and the RIE.

In the present embodiment, each of the layers constituting the MTJ element 130 is etched in such a manner that the MTJ element fits within the upper surface of the tantalum layer 107 on the silicon dioxide film 106. This is possible because the layers such as the tantalum layer 107, first magnetic layer 108, tunnel barrier layer 109 formed on the silicon dioxide film 106 are flat and free from the seam in the step of FIG. 5. The MTJ element 130 comprises high-quality layers 108, 109 and 111, therefore the MTJ element 130 has satisfactory characteristics.

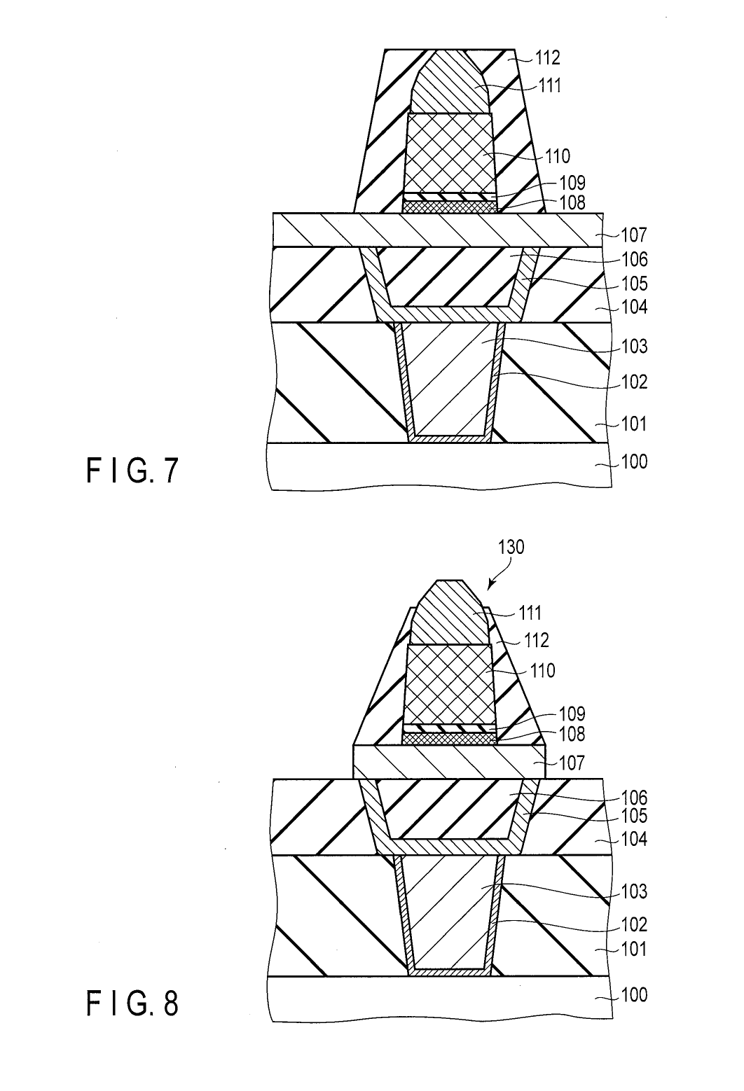

In order to fit the MTJ element 130 within the upper surface of the tantalum layer 107 on the silicon dioxide film 106, for example, the sizes of the silicon dioxide film 106 and the MTJ element 130 are determined such that the distance (margin) L between the edge of the MTJ element 130 and the conductive film 105 becomes a certain value or more.

[FIG. 7]

A sidewall insulating film 112 is formed on the MTJ element 130 in such a manner as to cover the sidewalls of the first magnetic layer 108, tunnel barrier layer 109, second magnetic layer 110 and hard mask 111. The sidewall insulating film 112 may be further formed on the sidewall (not shown) of the tantalum layer 107 in same cases. The sidewall insulating film 112 is a silicon nitride film, for example.

[FIG. 8]

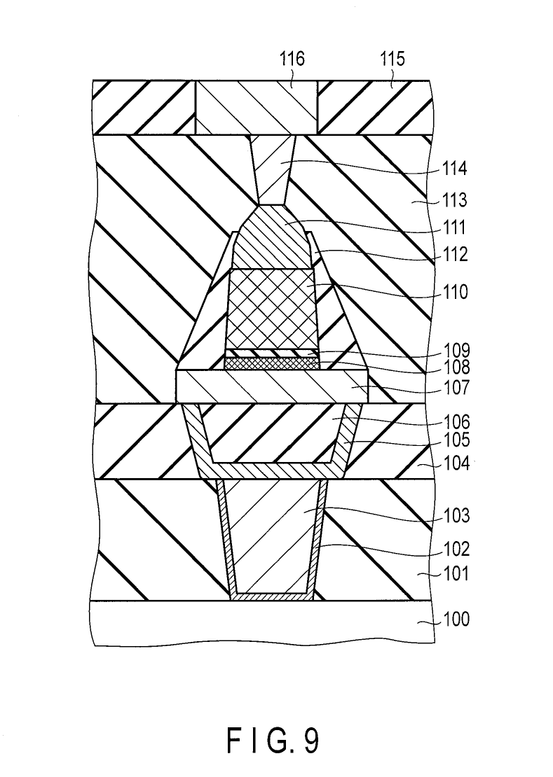

Using the hard mask 111 and sidewall insulating film 112 as masks, the tantalum layer 107 is etched. The edge of the tantalum layer 107 is located on the interlayer dielectric film 104 outside the conductive film 105. As a result, the lower electrode 103 is electrically connected to the MTJ element via the conductive film 105 and tantalum layer 107.

[FIG. 9]

An interlayer dielectric film 113 is formed on the entire surface of the MTJ element side, and a surface of the interlayer dielectric film 113 is planarized by CMP process. In some cases, a SiN passivation film is deposited by CVD or ALD (atomic layer deposition) after the MTJ element is etched by IBE, thereby the interlayer dielectric film 113 is prevented from having film damage (not shown in FIG. 9). The interlayer dielectric film 113 is a silicon dioxide film, for example. The interlayer dielectric film 113 is formed by CVD process, for example.

An upper electrode 114 connected to the hard mask 111 is formed in the interlayer dielectric film 113 by using damascene process. This damascene process include etching the interlayer dielectric film 113 to form a through hole communicating the upper surface of the hard mask 111, so that a part of the upper surface of the hard mask 111 may be reduced by the RIE. The reduction of the hard mask 111 is not shown in FIG. 9. A material of the upper electrode 114 is tungsten, for example. Subsequently, an interlayer dielectric film 115 is formed on the interlayer dielectric 113, and then, by using damascene process, a wiring 116 connected to the upper electrode 114 is formed in the interlayer dielectric film 115. The material of the wiring 116 is copper, for example.

### Second Embodiment

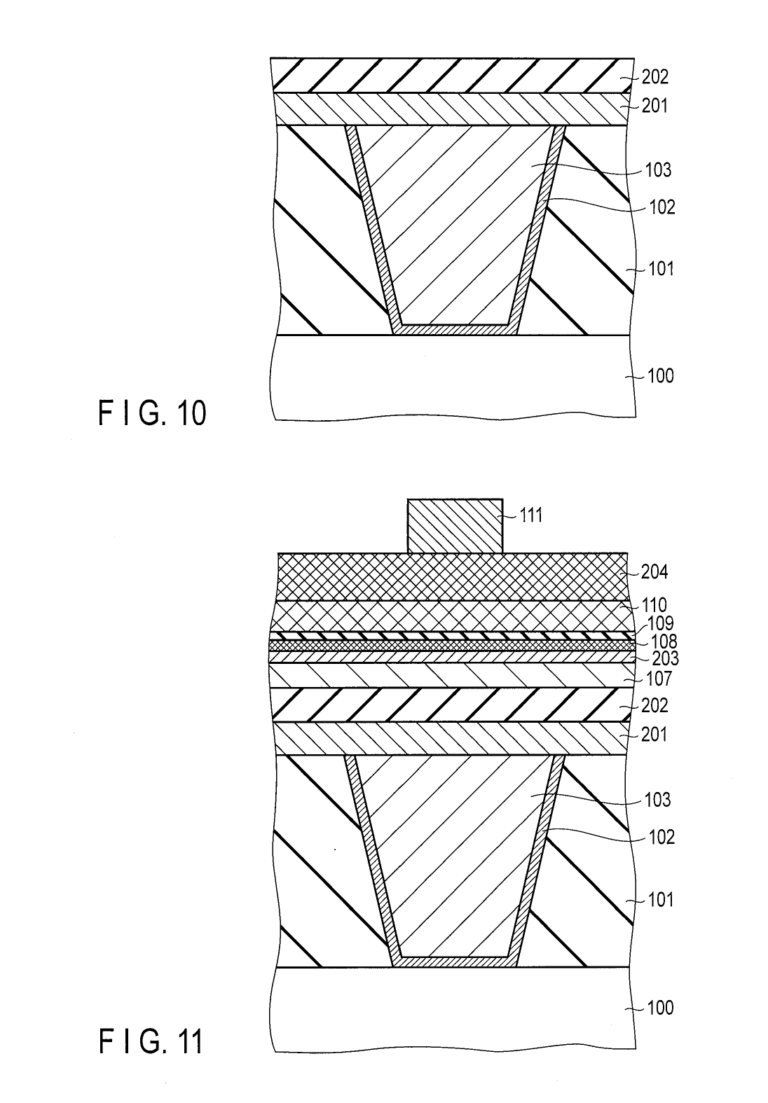

FIGS. 10 to 19 are sectional view for explaining a method for manufacturing a magnetic memory according to the present embodiment.

[FIG. 10]

In a manner similar to that of the first embodiment, the interlayer dielectric film 101, barrier metal film 102, lower electrode (plug) 103 are formed on the substrate (FIG. 1). The plane pattern of the lower electrode 102 is circular, and its diameter is, for example, 54 nm. Subsequently, for instance, a tantalum (underlying layer) 201 is formed on the interlayer dielectric film 101, barrier metal film 102 and lower electrode 103. A thickness of the tantalum layer 201 is 3 to 10 nm, for example, 5 nm. The tantalum layer 201 is formed in a region broader than a closed curve defining the contour of the upper surface of the pillared connecting member formed of the barrier metal film 102 and lower electrode 103. Instead of the tantalum layer 201, a titanium nitride (TiN) layer or a platinum (Pt) layer may be used.

A silicon oxide film 202 having an amorphous structure is formed on the tantalum layer 201. The silicon dioxide film 202 is formed by CVD process, for example. A thickness of the silicon dioxide film 202 is 3 to 10 nm, for example, 5 nm. The silicon dioxide film 202 is formed in a manner similar to that of the tantalum layer 201 in a region broader than the closed curve defining the contour of the upper surface of the connecting member (102 and 103). Instead of the silicon dioxide film 202, an amorphous silicon nitride film may be used. If the surface roughness of the silicon dioxide film 202 or the silicon nitride film is large, the surface of the silicon dioxide film 202 or the silicon nitride film may be planarized by CMP process.

Because of the influences of a seam (not shown) and a crystal grain boundary created in the lower electrode (plug) 103, a seam may be created in the tantalum layer 201. Since the amorphous silicon oxide film is formed without being affected by the tantalum layer 201 that is the underlying layer, so that the occurrence of a seam and a crack in the silicon oxide film 202 is suppressed.

[FIG. 11]

The layers constituting the MTJ element, which include the tantalum layer 107, layer (underlying layer) 203, first magnetic layer 108, tunnel barrier layer 109, second magnetic layer 110, and a shift cancelling layer 204, are formed consecutively on the silicon dioxide film 202. Subsequently, the hard mask 111 is formed on the shift cancelling layer 204.

Since a seam or the like is not created in the silicon oxide film 202, the high quality layers, which include the tantalum layer 107, Hf layer 203, first magnetic layer 108, tunnel barrier layer 109, second magnetic layer 110, shift cancelling layer 204, are formed on the silicon oxide film 202.

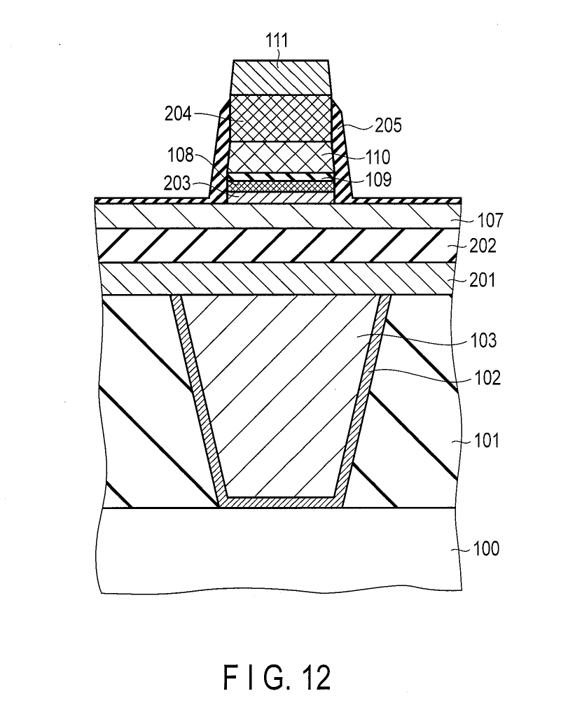

Although, in the present embodiment, the Hf layer is used as an underlying layer, instead of Hf as the material for the underlying layer, Ta, Zn, Cr, Nb, V, Mn, Zr, Pa, Ti, Al, Be, Th, Sc, Nd, Gd, Tb, Lu, Dy, or an alloy including at least two of the above mentioned element (including Hf) may be used. These materials are oxidized more easily than the materials constituting the MTJ element.

[FIG. 12]

Using the hard mask 111 as a mask, the shift cancelling layer 204, second magnetic layer 110, tunnel barrier layer 109, first magnetic layer 108, underlying layer 203, tantalum layer 107 are etched consecutively by IBE process.

The etching residue (Hf) produced by etching the layer 203 by BE process adheres to the sidewalls of the laminated body of layers 203, 108, 109, 110 and 204 and to most of the upper surface of the tantalum layer 107 on the periphery thereof to form a layer (conductive layer) of etching residue. Again, in this case and some cases, some part of the tantalum layer 107 is also etched. The etching amount of some part of the tantalum layer 107 is very small (for example, less than 1 nm), so that none of the tantalum layer 107 seems to be etched in FIG. 12.

The above conductive layer constitutes a leakage path between the first magnetic layer 108 and the second magnetic layer 110. As a result, the leakage current between the first magnetic layer 108 and the second magnetic layer 110 increases.

Here, in the present embodiment, the above conductive layer is transformed into an oxide layer (HfOx) 205 that is insulator by oxidization.

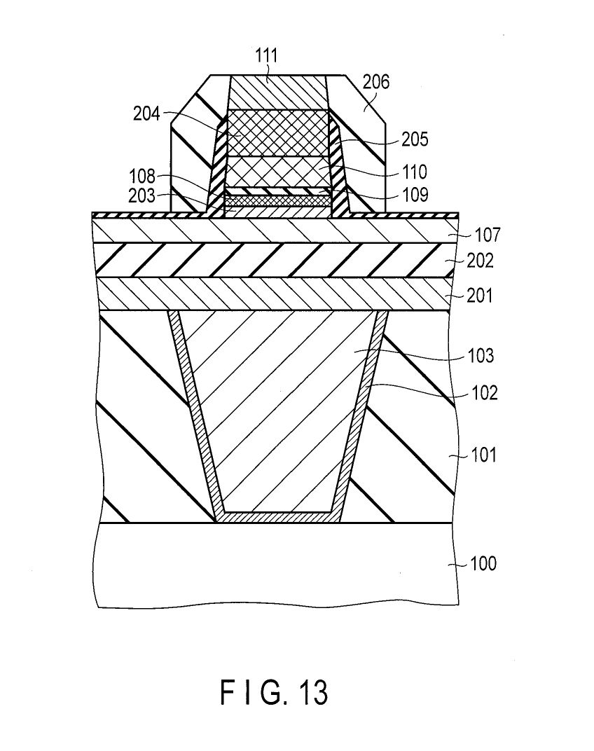

In FIG. 12, the laminated body including the shift cancelling layer 204, second magnetic layer 110, tunnel barrier layer 109, first magnetic layer 108, underlying layer 203 and tantalum layer 107 after the etching, is located within the closed curve defining the contour of the upper surface of the connecting member (102 and 103). However, as long as the laminated body is on the silicon dioxide film 202, the laminated body may include a portion located outside of the closed curve. For example, a width of the laminated body may be greater than a width of the connecting member. Since the laminated body on the silicon dioxide film 202 is of high quality, the characteristics of the MTJ element will not be influenced even if the width of the laminated body is set to be greater than the width of the connecting member (102 and 103). Therefore, the MTJ element of the present embodiment has a structure advantageous to miniaturization of the connecting member (102 and 103).

[FIG. 13]

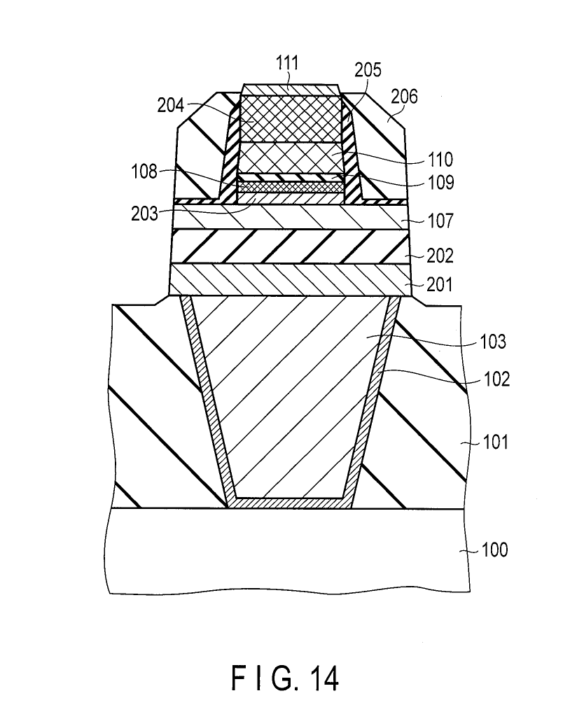

A sidewall insulating film 206 is formed on side surfaces of the hard mask 111, shift cancelling layer 204 and oxide layer 205 by depositing an insulating film to be the sidewall insulating film 206, and etching back the insulating film. The insulating film is a silicon nitride film, and the silicon nitride film is deposited, for example, by CVD process or ALD process. The silicon nitride film is etched back by RIE (reactive ion etching) process, for example.

[FIG. 14]

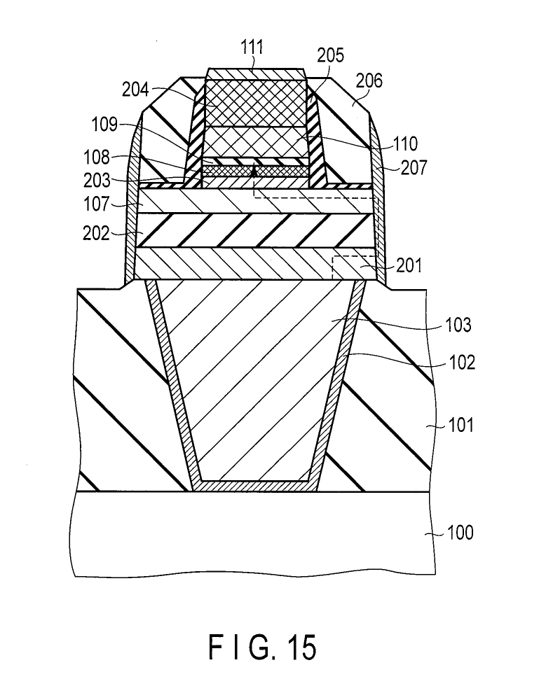

Using the hard mask 111 and sidewall insulating film 206 as masks, the oxide layer 205, tantalum layer 107, silicon dioxide film 202 and tantalum 201 are etched in such a manner that the surface of the interlayer dielectric film 101 is exposed. In this etching, the hard mask 111 and the sidewall insulating film 206 become thinner. The above etching is performed by using, for example, RIE, IBE, or a combination of RIE and IBE.

[FIG. 15]

A conductive layer, which is to be processed into a local interconnect 207, is deposited on the entire surface, and subsequently the local interconnect 207 is formed by etching back the conductive layer. In the present embodiment, the conductive layer is a TiN layer.

As a result, the lower electrode 103 is electrically connected to the first magnetic layer 108 via a path 331 of the tantalum layer 201, local interconnect 207, tantalum layer 107 and Hf layer 203.

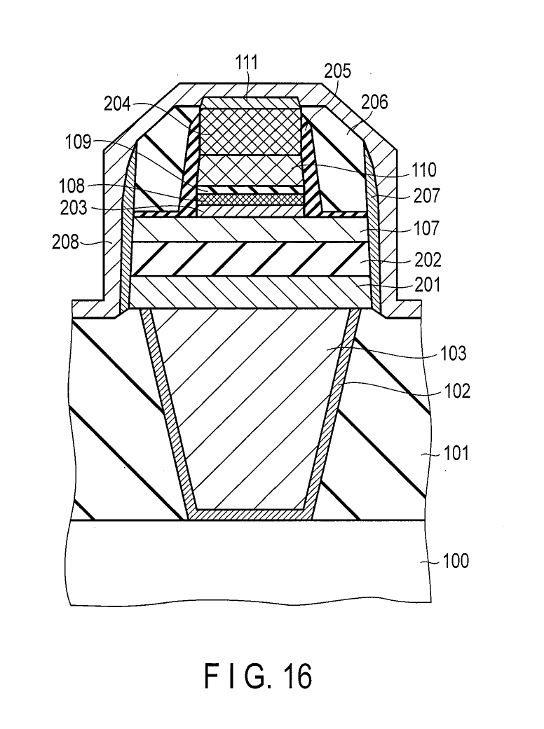

In the present embodiment, the local interconnect 207 is formed on the side surfaces of the tantalum layer 201, silicon dioxide film 202, tantalum layer 107, oxide layer 205 and sidewall insulating film 206. However, the local interconnect 207 may not be formed on the side surfaces of the oxide film 205 and sidewall insulating film 206. Because the lower electrode 103 and the first magnetic layer 108 are electrically even if the local interconnect 207 does not exist on the side surfaces of the layer 205 and 206.

[FIG. 16]

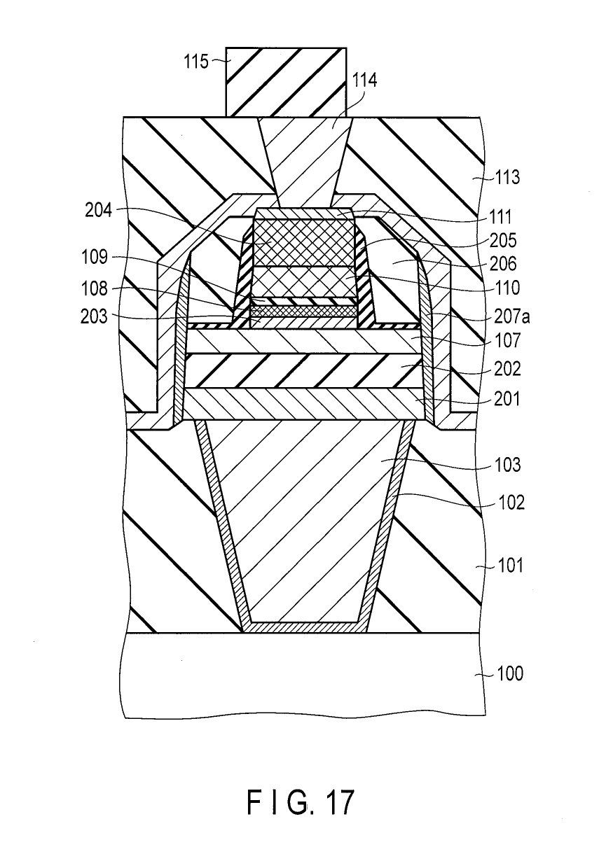

A passivation film is formed on the expose surfaces of the sidewall insulating film 206, local interconnect 207 and hard mask 111. The passivation film 208 is a silicon nitride film, for example.

[FIG. 17]

The interlayer dielectric film 113 is formed on the passivation film 208, thereafter the upper electrode 114, interlayer dielectric film 115, interconnection 116 are formed in a manner similar to that of the first embodiment. Similar to the first embodiment, the interlayer dielectric film 113 is etched by RIE to form the through hole communicating the upper surface of the hard mask 111, so that a part of the upper surface of the hard mask 111 may be reduced by the RIE. The reduction of the hard mask 111 is not shown in FIG. 17.

### Third Embodiment

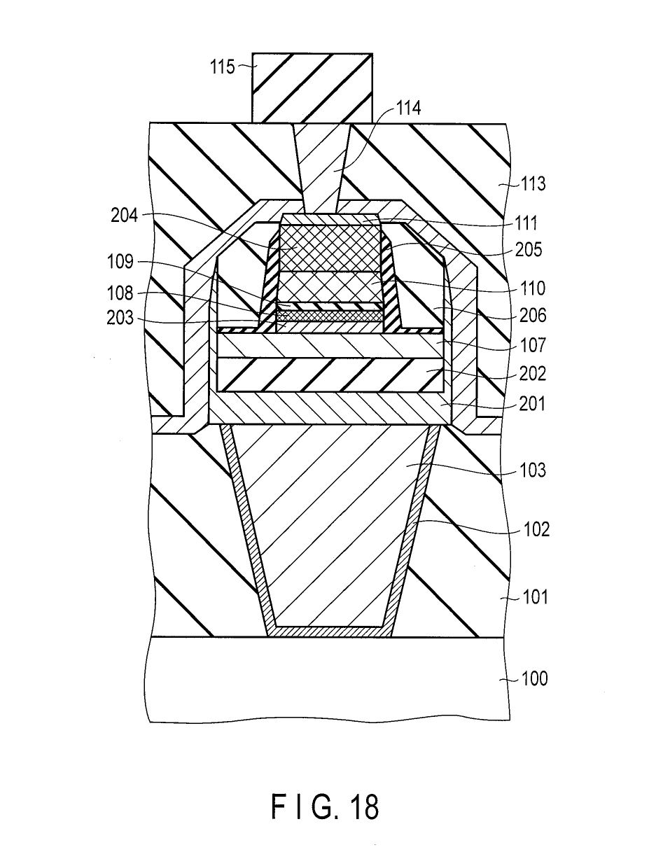

FIG. 18 is a sectional view showing a magnetic memory according to a third embodiment.

The present embodiment is different from the second embodiment in respect of the material of the local interconnect. In the second embodiment, the local interconnect 207 and the underlying layer 201 are formed of materials different from each other. In the present embodiment, on the other hand, the material of the local interconnect 207a includes the material of the underlying layer 201. The magnetic memory with such a configuration is obtained by the following manufacturing method, for example.

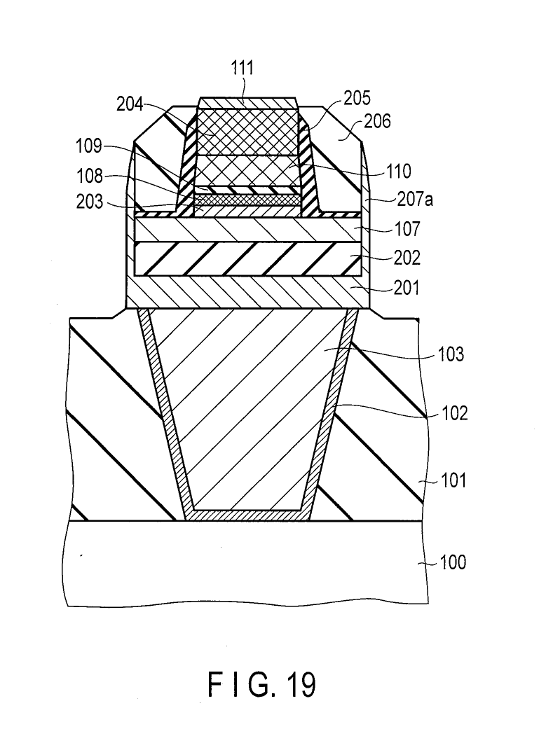

After the step of FIG. 13 in the second embodiment, as shown in FIG. 19, using the hard mask 111 and sidewall insulating film 206 as a mask, the oxide layer 205, tantalum layer 107, silicon dioxide film 202 and underlying layer 201 are etched by IBE process, or a combination of IBE and RIE processes.

Here, the conditions of the IBE process or of the combination of the IBE and RIE processes are adjusted such that the local interconnect 207a including the etching residue of the underlying layer 201 is formed on the side surfaces of the underlying layer 201, silicon dioxide film 202, tantalum layer 107, oxide layer 205, and sidewall insulating film 206. This adjustment is performed based on the thickness, material, or the like of each of the layers constituting the laminated body to be etched.

In the present embodiment, a platinum layer is used as the underlying layer 201. Because the platinum is hardly oxidized, and the occurrence of a leakage path between the first magnetic layer 108 and the second magnetic layer 110 is suppressed.

As described above in the second embodiment, the local interconnect 207a may not be formed on the side surfaces of the oxide layer 205 and sidewall insulating film 206.

The processes similar to those of the second embodiment will subsequently be performed to obtain the magnetic memory shown in FIG. 18.

Similar to the first embodiment, the interlayer dielectric film 113 is etched by RIE to form the through hole communicating the upper surface of the hard mask 111, so that a part of the upper surface of the hard mask 111 may be reduced by the RIE. The reduction of the hard mask 111 is not shown in FIG. 18.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
a substrate;
an electrode provided on the substrate;
a member provided on the electrode and having an amorphous structure; and
a magnetoresistive element provided on the member, wherein the magnetoresistive element is located within a closed curve defining a contour of an upper surface of the member.

2. The magnetic memory according to claim 1, further comprising:
a conductive member provided in a periphery of the member; and
a conductive layer provided between the member and the magnetoresistive element and connected to the conductive member and the magnetoresistive element.

3. The magnetic memory according to claim 2, wherein the conductive member covers a side surface and a bottom surface of the member.

4. The magnetic memory according to claim 2, further comprising an insulating film, and wherein the conductive member is provided on a side surface and a bottom surface of a through hole formed in the insulating film, and the member fills the through hole via the conductive member.

5. The magnetic memory according to claim 1, wherein an upper surface of the insulating member is flat.

6. The magnetic memory according to claim 1, wherein the magnetoresistive element comprises:
a first magnetic layer;
a non-magnetic layer provided on the first magnetic layer; and
a second magnetic layer provided on the non-magnetic layer.

7. The magnetic memory according to claim 1, wherein the electrode has crystallinity.

8. The magnetic memory according to claim 1, wherein the member is an insulating member.

9. A magnetic memory comprising:
a substrate;
an electrode provided on the substrate;
a first conductive layer provided on the electrode;
an insulating layer provided on the first conductive layer and having an amorphous structure;
a second conductive layer provided on the insulating layer;
a third conductive layer provided on side surfaces of the first conductive layer, insulating layer, and second conductive layer, and connected to the electrode; and
a magnetoresistive element provided on the second conductive layer.

10. The magnetic memory according to claim 9, wherein a material of the first conductive layer is different from a material of the third conductive layer.

11. The magnetic memory according to claim 9, wherein a material of the first conductive layer includes a material of the third conductive layer.

12. The magnetic memory according to claim 11, wherein the material of the first conductive layer includes platinum.

13. The magnetic memory according to claim 9, further comprising an insulating film provided on a sidewall of the magnetoresistive element.

14. The magnetic memory according to claim 9, wherein the conductive material includes at least one of Hf, Ta, Zn, Cr, Nb, V, Mn, Zr, Pa, Ti, Al, Be, Th, Sc, Nd, Gd, Tb, Lu and Dy.

15. The magnetic memory according to claim 9, wherein the electrode has crysrtallinity.

16. A method for manufacturing a magnetic memory comprising:
forming an electrode on a substrate;
forming an insulating film in a region including the electrode;
forming a through hole communicating with the electrode in the insulating film;
filling the through hole with a conductive layer and a amorphous member, the conductive layer covering a side surface and a bottom surface of the through hole, and the member filling the through hole via the conductive layer; and
forming a magnetoresistive element on the member, the magnetoresistive element being located within a closed curve defining a contour of an upper surface of the member.

17. The method according to claim 16, wherein filling the through hole with the conductive layer and the member includes planarizing an upper surface of the member by CMP (chemical mechanical polishing) process.

18. The method according to claim 16, wherein forming the magnetoresistive element comprises:
forming a laminated body comprising a plurality of layers which is to be the magnetoresistive element, on upper surfaces of the insulating film, the conductive layer and the member, and
processing the laminated body such that the magnetoresistive element is located within a closed curve defining a contour of the upper surface the member.

19. The method according to claim 16, wherein processing the laminated body comprises using at least of one of RIE (reactive ion etching) and IBE (ion beam etching).

20. The magnetic memory according to claim 16, wherein the member is an insulating member.
